(19) United States
(12) Patent Application Publication
(10) Pub. No.: US 2025/0393279 A1
(43) Pub. Date: Dec. 25, 2025

(54) SHIELDED-GATE TRENCH MOSFET TRANSISTOR WITH AN IMPROVED EDGE STRUCTURE AND RELATED MANUFACTURING PROCESS

(71) Applicant: STMicroelectronics International N.V., Geneva (CH)

(72) Inventors: Giuseppina VALVO, Catania, CT (IT); Davide Giuseppe PATTI, Mascalucia (CT) (IT); Andrea Mario TORTI, Monza (IT); Riccardo PEREGO, Milano, MI (IT)

(73) Assignee: STMicroelectronics International N.V., Geneva (CH)

(21) Appl. No.: 19/243,109

(22) Filed: Jun. 19, 2025

(30) Foreign Application Priority Data
Jun. 21, 2024 (IT) 102024000014395

(51) Int. Cl. H10D 64/00; H10D 30/01; H10D 30/66

(52) U.S. Cl. CPC H10D 64/117; H10D 30/0297; H10D 30/668

(57) ABSTRACT

A MOSFET transistor includes a semiconductor body having internal trenches with elongated shapes parallel to a first direction and arranged in succession and a pair of edge trenches having elongated shapes parallel to a second direction. Ends of each internal trench communicate with a corresponding edge trench. Each edge trench includes a corresponding dielectric trench region. Each internal trench includes a conductive shield region extending inside the internal trench and having an elongated shape parallel to the first direction. A pair of conductive gate regions extend into the internal trench on opposite sides of the conductive shield region and have elongated shapes parallel to the first direction. Ends of each conductive shield region penetrate inside a corresponding edge trench. In each edge trench, the ends of adjacent conductive shield regions are separated from each other.

### PRIORITY CLAIM

This application claims the priority benefit of Italian Application for Patent No. 102024000014395 filed on Jun. 21, 2024, the content of which is hereby incorporated by reference in its entirety to the maximum extent allowable by law.

### TECHNICAL FIELD

The present invention relates to a shielded-gate trench MOSFET transistor with an improved edge structure. Furthermore, the present invention concerns the related manufacturing process for making the shielded-gate trench MOSFET transistor.

### BACKGROUND

As is known, in the field of field effect transistors for power applications, such as for example shielded-gate trench MOSFET transistors, there is a need for transistors that have a high breakdown voltage, in particular the so-called drain-source breakdown voltage with third terminal to ground (referred to in the art as the voltage BVDSS).

A possible solution to increase the voltage BVDss is shown qualitatively in FIG. 1 and envisages, in a semiconductor body 2, separating the ends of the trenches (indicated by Tg in FIG. 1) which house the gate structures and the shield structures (not shown in FIG. 1) from the perimeter trench (indicated by Tp in FIG. 1). In particular, the each end of trench Tg is spaced by a distance d from the perimeter trench Tp, so as to avoid the formation of joined trenches with ‘T’-shaped profiles. However, the distance d needs to be compatible with the production processes adopted. Furthermore, controlling the distance d may be difficult.

There is a need in the art to provide a shielded-gate trench MOSFET transistor capable of overcoming, at least in part, the drawbacks of the prior art.

### SUMMARY

An embodiment comprises a shielded-gate trench MOSFET transistor.

An embodiment comprises a manufacturing process for making a shielded-gate trench MOSFET transistor.

In an embodiment, a MOSFET transistor comprises: a semiconductor body; a plurality of internal trenches, extending into the semiconductor body, having elongated shapes parallel to a first direction and arranged in succession; and a pair of edge trenches, extending into the semiconductor body and having elongated shapes parallel to a second direction transversal to the first direction, wherein each internal trench has ends that each communicate with a corresponding edge trench.

The MOSFET transistor further comprises, for each edge trench, a corresponding dielectric trench region, extending into the edge trench.

The MOSFET transistor still further comprises, for each internal trench: a conductive shield region, which extends inside the internal trench and has an elongated shape parallel to the first direction; and a first pair of conductive gate regions, which extend into the internal trench on opposite sides of the conductive shield region and have elongated shapes parallel to the first direction. Each conductive shield region has ends that each penetrate inside a corresponding edge trench. In each edge trench, ends of adjacent conductive shield regions are separated from each other.

In an embodiment, a process for manufacturing a MOSFET transistor comprises: forming a plurality of internal trenches, extending into the semiconductor body, which have elongated shapes parallel to a first direction and are arranged in succession; and forming a pair of edge trenches, extending into the semiconductor body and having elongated shapes parallel to a second direction transversal to the first direction, each internal trench having ends that each communicate with a corresponding edge trench.

The manufacturing process further comprises forming, in each edge trench, a corresponding dielectric trench region.

The manufacturing process still further comprises, for each internal trench: forming a conductive shield region extending inside the internal trench and having an elongated shape parallel to the first direction; and forming a first pair of conductive gate regions extending into the internal trench on opposite sides of the conductive shield region and having elongated shapes parallel to the first direction.

Each conductive shield region has ends that each penetrate inside a corresponding edge trench. At each edge trench, the ends of adjacent conductive shield regions are separated from each other.

### BRIEF DESCRIPTION OF THE FIGURES

For a better understanding of the present invention, embodiments thereof are now described, purely by way of non-limiting example, with reference to the attached drawings, wherein:

FIG. 1 schematically shows a top view of a semiconductor body housing trenches;

FIG. 2 schematically shows a top view of a section of a transistor, taken along a section line II-II shown in FIG. 3;

FIG. 3 schematically shows a portion of a section of the transistor shown in FIG. 2, taken along a section line III-III shown in FIG. 2;

FIG. 4 schematically shows a portion of a section of the transistor shown in FIG. 2, taken along a section line IV-IV shown in FIG. 2;

FIG. 5 schematically shows a portion of a section of the transistor shown in FIG. 2, taken along a section line V-V shown in FIG. 2;

FIG. 6 schematically shows a top view of a section of a variant of the present transistor, taken along a section line VI-VI shown in FIG. 7;

FIG. 7 schematically shows a portion of a section of the transistor shown in FIG. 6, taken along a section line VII-VII shown in FIG. 6;

FIG. 8 schematically shows a portion of a section of the transistor shown in FIG. 6, taken along a section line VIII-VIII shown in FIG. 6;

FIGS. 9A-14A schematically show a portion of the transistor shown in FIGS. 2-5, taken along the section line IV-IV, during subsequent steps of a manufacturing process;

FIGS. 9B-14B schematically show a portion of the transistor shown in FIGS. 2-5, taken along the section line III-III, during the same steps of the manufacturing process to which

FIGS. 9A-14A refer, respectively;

FIG. 12C schematically shows a top view of a portion of the transistor shown in FIGS. 2-5, during the same step of the manufacturing process to which FIGS. 12A and 12B refer;

FIGS. 15A and 15B schematically show top views of different portions of the transistor shown in FIGS. 6-8, during a same step of the manufacturing process;

FIG. 15C schematically shows a portion of a section of the transistor shown in FIGS. 15A and 15B, taken along a section line XV-XV shown in FIG. 15B; and

FIG. 16 schematically shows a top view with portions removed of a portion of a further variant of the present transistor.

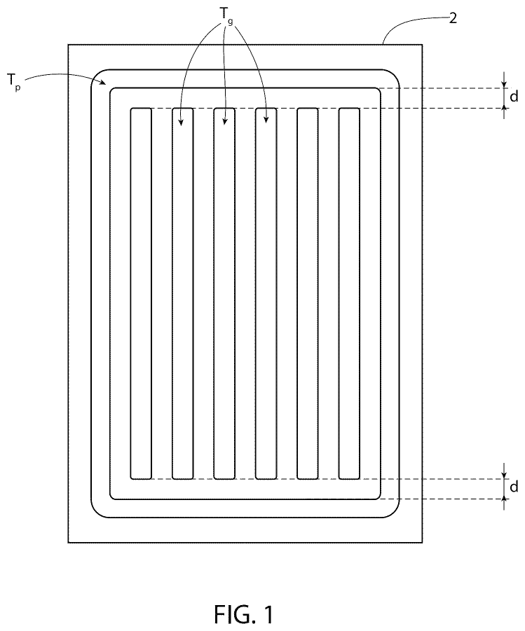

### DETAILED DESCRIPTION

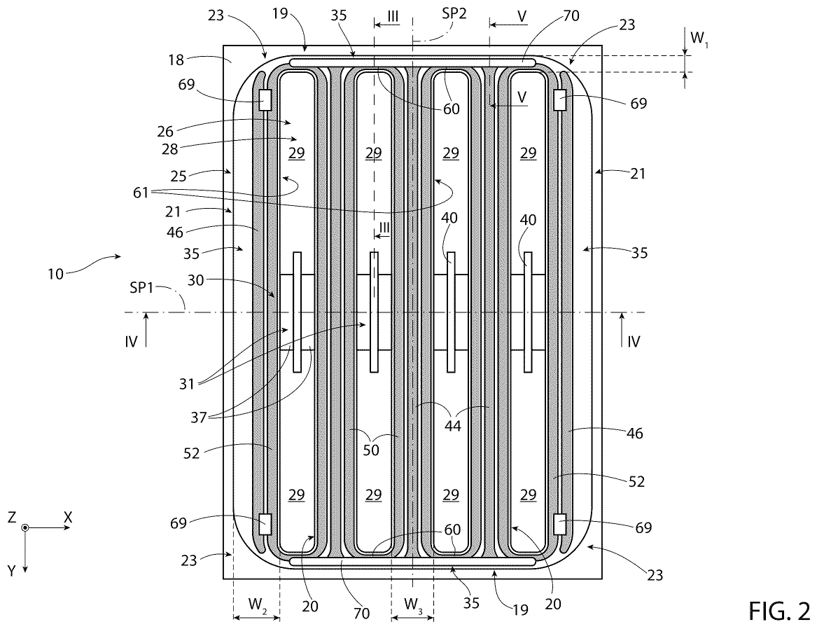

FIGS. 2-5 show a transistor 10, which is a shielded-gate trench MOSFET transistor, illustrated in an orthogonal reference system XYZ.

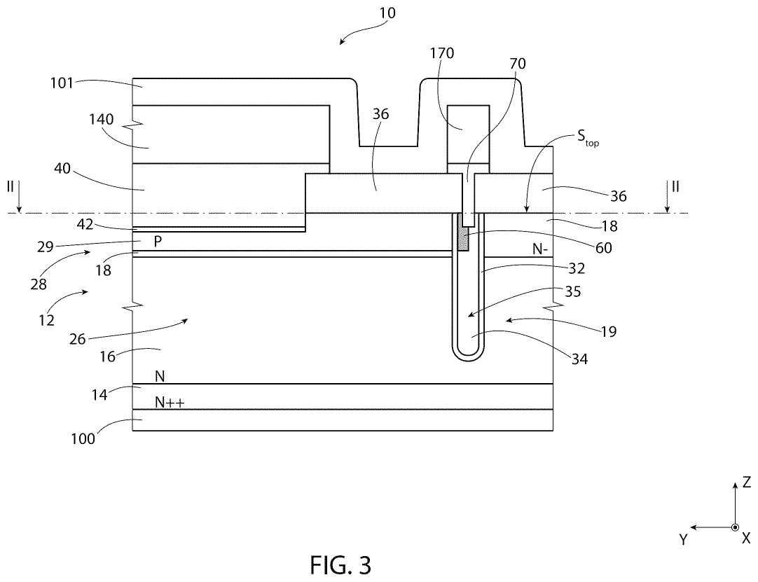

As shown in FIG. 3, the transistor 10 comprises a semiconductor body 12, which is formed for example by silicon and comprises a substrate 14 with N++ type doping, which has a thickness comprised for example between 20 μm and 200 μm and has a doping level comprised for example between 3*10¹⁹ and 8*10¹⁹ atoms/cm³.

The semiconductor body 12 also comprises a first epitaxial layer 16 with N-type doping, which is arranged above the substrate 14, in direct contact, has a thickness comprised for example between 1 μm and 15 μm and has a doping level comprised for example between 2*10¹⁶ and 7*10¹⁶ atoms/cm³.

The semiconductor body 12 also comprises a second epitaxial layer 18 with N-type doping, which is arranged above the first epitaxial layer 16, in direct contact, has a thickness comprised for example between 1 μm and 3 μm and has a doping level comprised for example between 9*10¹⁴ and 10¹⁶ atoms/cm³. Furthermore, the second epitaxial layer 18 is delimited at the top by a front surface Sₜₒₚ, which is approximately parallel to the XY plane and delimits at the top the semiconductor body 12.

A pair of first perimeter trenches 19 and a pair of second perimeter trenches 21 extend inside the semiconductor body 12, starting from the front surface Sₜₒₚ.

Without any loss of generality, the first and the second perimeter trenches 19, 21 substantially have a same depth (along the Z axis), such that the first and the second perimeter trenches 19, 21 entirely traverse the second epitaxial layer 18 and traverse an upper part of the first epitaxial layer 16, without traversing the substrate 14. In other words, the bottom of each of the first or second perimeter trenches 19, 21 extends into the first epitaxial layer 16 and overlies, at a distance, the substrate 14.

Again, without any loss of generality, the transistor 10 is approximately symmetrical with respect to a first symmetry plane SP1, which is parallel to the XZ plane, and with respect to a second symmetry plane SP2, which is parallel to the YZ plane. This having been said, and again without any loss of generality, the first perimeter trenches 19 extend parallel to the first symmetry plane SP1 and are arranged symmetrically with each other with respect to the first symmetry plane SP1; the second perimeter trenches 21 extend parallel to the second symmetry plane SP2 and are arranged symmetrically with each other with respect to the second symmetry plane SP2.

In practice, in top view, the first and the second perimeter trenches 19, 21 are arranged along the sides of a rectangle. The first and the second perimeter trenches 19, 21 are therefore arranged angularly alternating to each other.

In greater detail, and without any loss of generality, in top view the first perimeter trenches 19 have elongated shapes parallel to the X axis and have a same width W₁ (measured along the Y axis), which is approximately invariant for translations along the X axis. The second perimeter trenches 21 have elongated shapes parallel to the Y axis and have a same width W₂ (measured along the X axis), which is approximately invariant for translations along the Y axis and is greater than the width W₁. For example, the width W₁ may be comprised between 0.5 μm and 1 μm, while the width W₂ may be comprised between 1.5 μm and 2 μm.

As visible in FIG. 2, the transistor 10 comprises four corner trench portions 23, which extend into the semiconductor body 12 starting from the front surface Sₜₒₚ and have approximately the same depth as the first and the second perimeter trenches 19, 21. Furthermore, each corner trench portion 23 is interposed between an end of a corresponding first perimeter trench 19 and an end of a corresponding second perimeter trench 21, which are put in communication with each other by the corner trench portion 23.

In top view, the corner trench portions 23 have curved shapes. Furthermore, the first and the second perimeter trenches 19, 21 and the corner trench portions 23 form an edge trench 25, which has an annular shape (in particular, in top view it has the shape of a rectangle with beveled vertices) and laterally delimits an internal region 26 of the semiconductor body 12.

Furthermore, a plurality of internal trenches 20 extends inside the semiconductor body 12; only for simplicity of representation and description, therefore without any loss of generality, it is assumed that the internal trenches 20 are three in number and are substantially equal to each other.

In detail, the internal trenches 20 extend into the semiconductor body 12 starting from the front surface Sₜₒₚ and have approximately the same depth as the first and the second perimeter trenches 19, 21, therefore they traverse the second epitaxial layer 18 and part of the first epitaxial layer 16. Furthermore, the internal trenches 20 extend parallel to the second symmetry plane SP2 and are arranged offset parallel to the X axis, within the internal region 26 of the semiconductor body 12.

In even greater detail, in top view, the internal trenches 20 have elongated shapes parallel to the Y axis and have a same width W₃ (measured along the X axis), which is approximately invariant for translations along the Y axis. The relationship W₃>W₁ applies. Furthermore, the relationship W₂>W₃ may apply. For example, the width W₃ may be comprised between 1.3 μm and 2 μm. Furthermore, each internal trench 20 has a pair of ends, each of which communicates with a corresponding first peripheral trench 19.

The semiconductor body 12 also comprises a body region 28 of P-type, which extends, starting from the front surface Sₜₒₚ, into the portion of the second epitaxial layer 18 laterally delimited by the edge trench 25. The body region 28 has a doping level comprised for example between 10¹⁴ and 6*10¹⁶ atoms/cm³ and has a thickness lower than the thickness of the second epitaxial layer 18, in such a way that a portion of the second epitaxial layer 18 extends below the body region 28. For example, the body region 28 has a thickness comprised between 0.3 μm and 0.4 μm.

Furthermore, the body region 28 is traversed by the internal trenches 20, which divide the body region 28 into body subregions 29 spatially separated from each other. In the example shown in FIGS. 2-5, the body subregions 29 are four in number.

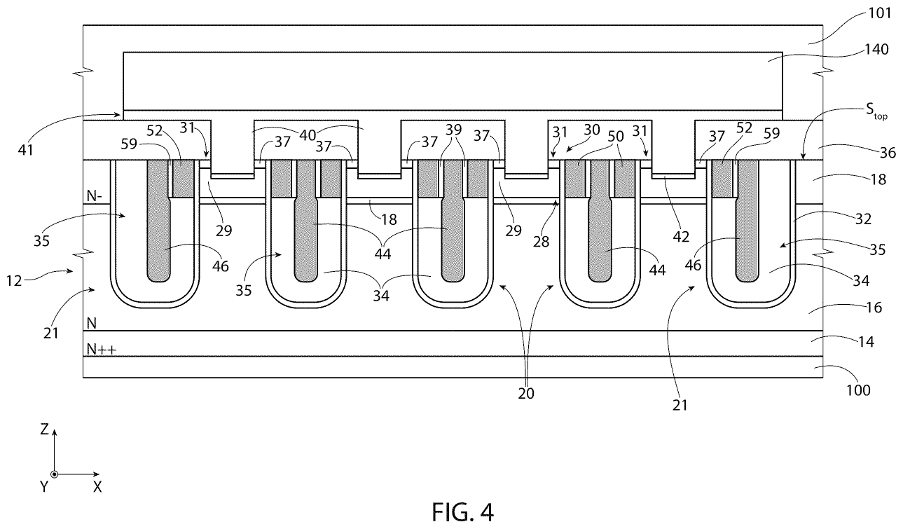

As visible in FIGS. 2 and 4, the semiconductor body 12 also comprises a source region 30 of N++ type, which extends, starting from the front surface Sₜₒₚ, in a part of the body region 28. The source region 30 has a doping level comprised for example between 10¹⁷ and 1020 atoms/cm³ and has a lower thickness than the thickness of the body region 28, in such a way that a portion of the body region 28 extends below the source region 30. For example, the source region 30 has a thickness comprised between 0.2 μm and 0.3 μm.

In greater detail, as visible in FIG. 2, in top view the source region 30 has an approximately rectangular shape, elongated parallel to the X axis. Furthermore, the source region 30 extends between the second perimeter trenches 21, wherewith it is in direct contact, at a distance from the first perimeter trenches 19, and is traversed by the internal trenches 20, which divide the source region 30 into source region subparts 31 spatially separated from each other. The source region 30 therefore leaves exposed two portions of the body region 28, which extend on opposite sides of the source region 30, face the front surface Sₜₒₚ and contact, each, a corresponding first perimeter trench 19.

The side walls and the bottom of each first perimeter trench 19, of each second perimeter trench 21 and of each internal trench 20 are coated by a corresponding external dielectric layer 32, which is formed, for example, by thermal oxide and has a thickness comprised for example between 0.7 μm and 1 μm. Furthermore, inside each first perimeter trench 19, each second perimeter trench 21 and each internal trench 20, a corresponding internal dielectric region 34 is present, which is formed for example by TEOS oxide and is surrounded laterally and at the bottom, in direct contact, by the corresponding external dielectric layer 32. In practice, each external dielectric layer 32 and each internal dielectric region 34 form a corresponding dielectric trench region 35; in this regard, for ease of view, in FIG. 2 the distinction between external dielectric layers 32 and internal dielectric regions 34 is not shown. Furthermore, the external dielectric layers 32 contact each other so as to form a single thermal oxide structure, while the internal dielectric regions 34 contact each other so as to form a single TEOS oxide structure.

In practice, as visible in FIG. 2, on the opposite sides of each internal trench 20 a pair of corresponding body subregions 29 and a pair of corresponding source region subparts 31 extend, which, as visible in FIG. 4, contact corresponding portions of the external dielectric layer 32 of the internal trench 20; further portions of the external dielectric layer 32 contact, instead, corresponding portions of the first and the second epitaxial layers 16, 18. As regards, instead, the first perimeter trenches 19, as visible in FIGS. 2 and 3, on the side of each first perimeter trench 19 arranged facing the internal region 26, the body subregions 29 extend, which contact corresponding portions of the external dielectric layer 32 of the first perimeter trench 19. As regards, instead, the second perimeter trenches 21, on the side of each second perimeter trench 21 arranged facing the internal region 26 a corresponding body subregion 29 and a corresponding source region subpart 31 extend, which contact corresponding portions of the part of the corresponding external dielectric layer 32 arranged facing the internal region 26, as visible in FIG. 4.

A front dielectric region 36, formed for example by oxide and silicon nitride, extends above the front surface Sₜₒₚ.

The transistor 10 further comprises, for each body subregion 29, a corresponding body-source contact region 40, which, although not shown, may be formed by one or more respective metal material regions. For example, each body-source contact region 40 may be formed by a respective multilayer structure (not shown) including a first layer of titanium nitride (TiN) and an overlying second layer of tungsten (W). In top view, the body-source contact region 40 has, for example, an approximately rectangular shape, elongated parallel to the Y axis, and is arranged approximately at the center of the respective body subregion 29, at a distance from the first perimeter trenches 19. Furthermore, in the event that the body subregion 29 is delimited by a pair of internal trenches 20, the body-source contact region 40 extends at a distance from the pair of internal trenches 20; in the event that the body subregion 29 is delimited by an internal trench 20 and a second perimeter trench 21, the body-source contact region 40 extends at a distance from the internal trench 20 and from the second perimeter trench 21.

In greater detail, each body-source contact region 40 extends vertically through the front dielectric region 36 and through part of the corresponding body subregion 29, without contacting the second epitaxial layer 18. A corresponding portion of the corresponding body subregion 29 is therefore present below each body-source contact region 40.

In even greater detail, the body-source contact regions 40 have shapes approximately symmetric with respect to the first symmetry plane SP1. Furthermore, without any loss of generality, parallel to the Y axis, the body-source contact regions 40 have a greater extension than the extension of the source region 30. Furthermore, each body-source contact region 40 traverses the corresponding source region subpart 31 both vertically (i.e., parallel to the Z axis) and parallel to the Y axis, therefore divides the corresponding source region subpart 31 into a pair of source subregions 37, which are spatially separated from each other and extend on opposite sides of the body-source contact region 40, wherewith they are in direct contact.

As visible in FIG. 4, parts of the body-source contact regions 40 extend above the front dielectric region 36 so as to form a single conductive body-source contact structure 41, which puts the body region 28 and the source region 30 into contact.

For each body-source contact region 40, the semiconductor body 12 comprises a corresponding enriched body contact region 42 of P++ type, which has a doping level for example comprised between 10¹⁸ e 10¹⁹ atoms/cm³ and has a thickness comprised for example between 0.3 μm and 0.4 μm. In particular, each enriched body contact region 42 extends below the corresponding body-source contact region 40, in the portion of the corresponding body subregion 29 that is overlaid by the corresponding body-source contact region 40, at a distance from the second epitaxial layer 18; each enriched body contact region 42 contacts directly with the overlying body-source contact region 40 and improves the electrical contact between the latter and the body subregion 29. Furthermore, the enriched body contact regions 42 are separated from the source subregions 37.

The transistor 10 further comprises, for each internal trench 20, a corresponding shield region 44, which is formed by polysilicon and has a thickness (measured along the Z axis) greater than the thickness of the second epitaxial layer 18, and a pair of elongated gate regions 50, which are formed by polysilicon and have a thickness at least equal to, and preferably greater than, the thickness of the body region 28 and lower than the thickness of the shield region 44.

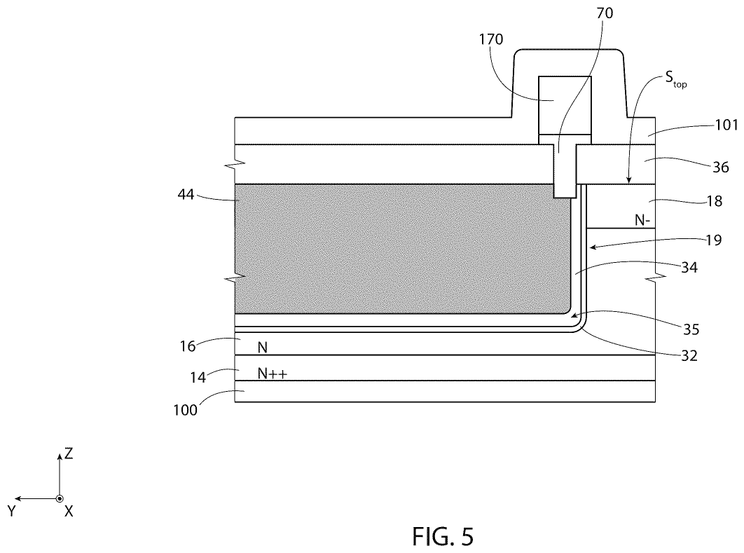

In detail, as a first approximation each shield region 44 faces the front surface Sₜₒₚ and extends vertically inside the corresponding internal trench 20. Furthermore, in top view, each shield region 44 has an elongated shape parallel to the Y axis and extends parallel to the Y axis in such a way that the ends of the shield region 44 each penetrate inside a corresponding first perimeter trench 19, as also visible in FIG. 5. In practice, in each first perimeter trench 19 a plurality of ends of the shield regions 44 is present, these ends being arranged approximately in succession parallel to the X axis, adjacent ends of the succession being separated from each other by portions of the dielectric trench region 35 present in the first perimeter trench 19.

In greater detail, as visible in FIG. 4, each shield region 44 extends inside the corresponding internal trench 20 in such a way that a lower portion of the shield region 44 is surrounded laterally and at the bottom, in direct contact, by the corresponding internal dielectric region 34. Furthermore, the dielectric trench region 35 of each internal trench 20 comprises a pair of dielectric coating layers 39 (not indicated in FIG. 2), which are formed, for example, by thermal oxide and coat the side walls of an upper portion of the shield region 44. In other words, the dielectric coating layers 39 extend on opposite sides of the upper portion of the shield region 44, have elongated shapes parallel to the Y axis, have a thickness (measured along the Z axis) approximately equal to the thickness of the elongated gate regions 50 and contact at the bottom with the corresponding internal dielectric region 34. Furthermore, as visible in FIG. 5, both the upper portion and the lower portion of each shield region 44 contact the internal dielectric regions 34 of the first perimeter trenches 19. In fact, in each first perimeter trench 19, parts of the corresponding internal dielectric region 34 laterally coat the upper portions of the corresponding ends of the shield regions 44 and face the front surface Sₜₒₚ, and furthermore other parts of the corresponding internal dielectric region 34 coat laterally and at the bottom, the lower portions of the corresponding ends of the shield regions 44.

Although not shown, end portions of the dielectric coating layers 39 may penetrate inside the first perimeter trenches 19.

In each internal trench 20, the corresponding two elongated gate regions 50 extend inside the internal trench 20 approximately starting from the front surface Sₜₒₚ, so as to extend on opposite sides of the upper portion of the shield region 44, up to contacting at the bottom the corresponding internal dielectric region 34.

In greater detail, as a first approximation the elongated gate regions 50 have elongated shapes parallel to the Y axis. Furthermore, each elongated gate region 50 laterally contacts, on one own first side, a corresponding dielectric coating layer 39, which is therefore interposed, in direct contact, between the elongated gate region 50 and the upper portion of the shield region 44, and furthermore contacts, on one own second side opposite to the first side, a portion of the corresponding external dielectric layer 32, which is therefore interposed, in direct contact, between the elongated gate region 50 and a corresponding body subregion 29.

In practice, in each internal trench 20, the corresponding internal dielectric region 34 extends below the corresponding dielectric coating layers 39 and the corresponding elongated gate regions 50, in direct contact.

The transistor 10 further comprises, for each second perimeter trench 21, a corresponding shield region 46 and a corresponding elongated gate region 52, which are formed by polysilicon.

As a first approximation, each shield region 46 faces the front surface Sₜₒₚ and extends vertically inside the corresponding second internal trench 21 with a thickness equal, for example, to the thickness of the shield regions 44. Furthermore, as a first approximation each shield region 46 has an elongated shape parallel to the Y axis and extends parallel to the Y axis in such a way that the ends of the shield region 46 each extend inside a corresponding corner trench portion 23, as visible in FIG. 2.

In greater detail, as visible in FIG. 4, each shield region 46 extends inside the corresponding second perimeter trench 21 in such a way that a lower portion of the shield region 46 is surrounded laterally and at the bottom, in direct contact, by the corresponding internal dielectric region 34. Furthermore, the dielectric trench region 35 of each second perimeter trench 21 comprises a respective dielectric coating layer 59 (not indicated in FIG. 2), which is formed, for example, by thermal oxide and coats, in direct contact, the side wall arranged facing the internal region 26 of the upper portion of the shield region 46, while the opposite side wall of the upper portion of the shield region 46 is coated by the corresponding internal dielectric region 34. In particular, the dielectric coating layer 59 has an elongated shape parallel to the Y axis and contacts at the bottom with the corresponding internal dielectric region 34. Although not shown, end portions of the dielectric coating layers 59 may penetrate inside corresponding corner trench portions 23.

In addition, each elongated gate region 52 has an elongated shape parallel to the Y axis and extends inside the corresponding second perimeter trench 21 approximately starting from the front surface Sₜₒₚ, with a thickness approximately equal to, for example, the thickness of the elongated gate regions 50. Furthermore, each elongated gate region 52 extends, in direct contact, between the corresponding dielectric coating layer 59, which has a thickness (measured along the Z axis) approximately equal to the thickness of the elongated gate region 52, and a portion of the corresponding external dielectric layer 32, which is therefore interposed, in direct contact, between the elongated gate region 52 and the corresponding body subregion 29. Furthermore, each elongated gate region 52 extends vertically up to contacting at the bottom the corresponding internal dielectric region 34. In other words, in each second perimeter trench 21, a part of the corresponding internal dielectric region 34 extends below the corresponding dielectric coating layer 59 and the corresponding elongated gate region 52.

In practice, each body subregion 29, as well as each source region subpart 31, is interposed between a pair of respective elongated gate regions (each pair being alternately formed by an elongated gate region 52 and an elongated gate region 50 or by two elongated gate regions 50, which are arranged facing the body subregion 29), whereto it is therefore electrically coupled, and wherefrom it is separated through portions of external dielectric layers 32. Again, in other words, observing that the elongated gate regions 52 of the second perimeter trenches 21 and the elongated gate regions 50 of the internal trenches 20 define one succession of elongated gate regions along the X axis, each body subregion 29 is interposed between two corresponding adjacent elongated gate regions of the succession. Furthermore, both the elongated gate regions 52 of the second perimeter trenches 21 and the elongated gate regions 50 of the internal trenches 20 have ends that penetrate inside the first perimeter trenches 19.

The transistor 10 further comprises, for each body subregion 29, a corresponding pair of transversal gate regions 60, each of which is formed by polysilicon and is arranged in a corresponding first perimeter trench 19, in such a way that the two transversal gate regions 60 are arranged in an approximately symmetrical manner with respect to the first symmetry plane SP1, on opposite sides of the body subregion 29. Furthermore, each transversal gate region 60 has ends connected to corresponding ends of the elongated gate regions which are electrically coupled to the body subregion 29, in such a way that the pair of transversal gate regions 60 form, together with such elongated gate regions, a single corresponding annular gate region 61, which has an approximately symmetrical shape with respect to the first symmetry plane SP1 and laterally surrounds the body subregion 29.

In greater detail, referring for brevity to a single first perimeter trench 19, as a first approximation the corresponding transversal gate regions 60 extend inside the first perimeter trench 19 starting from the front surface Sₜₒₚ, with approximately the same thickness as the elongated gate regions 50 and as the elongated gate regions 52. Furthermore, as visible in FIG. 3, each transversal gate region 60 is separated from the corresponding body subregion 29 by a portion of the external dielectric layer 32 of the first perimeter trench 19. This portion of the external dielectric layer 32 extends on one side of the transversal gate region 60, while the other side and the bottom of the transversal gate region 60 contact with the internal dielectric region 34 of the first perimeter trench 19.

The transistor 10 further comprises, for each first perimeter trench 19, a corresponding shield contact region 70, formed by conductive material. In this regard, although not shown in detail, the shield contact region 70 may be formed by one or more respective metal material regions, therefore it may be formed for example by a multilayer structure (not shown) including a first layer of titanium nitride (TiN) and an overlying second layer of tungsten (W). Without any loss of generality, the two shield contact regions 70 are approximately equal to each other and are arranged for example in an approximately symmetrical manner with respect to the first symmetry plane SP1.

In greater detail, in top view, the shield contact regions 70 have elongated shapes parallel to the Y axis. Furthermore, each shield contact region 70 extends through the front dielectric region 36, so as to penetrate inside an upper portion of the respective first perimeter trench 19 and contact the transversal gate regions 60 present in the first perimeter trench 19 and the ends of the shield regions 44 which extend into the first perimeter trench 19, as visible in FIGS. 3 and 5.

In even greater detail, the shield contact regions 70 have a thickness approximately invariant for translations parallel to the Y axis. Furthermore, referring for brevity to a single shield contact region 70, and without any loss of generality, it extends inside the semiconductor body 12 up to a depth that is approximately equal to the maximum depth reached by the body-source contact regions 40 and is lower than the maximum depth reached by the transversal gate regions 60; consequently, the shield contact region 70 extends partly inside the corresponding transversal gate regions 60 and the corresponding shield regions 44 and also contacts the internal dielectric region 34 of the corresponding first perimeter trench 19.

The transistor 10 further comprises: a lower metallization 100, functioning as a drain metallization, that is formed, for example, by a multilayer conductive structure (for example, formed by three layers of titanium, nickel-vanadium and silver) and extends below the substrate 14, in direct contact; a body-source metallization 140, which is formed, for example, by an aluminum and copper alloy and extends above the conductive body-source contact structure 41, in direct contact; and a shield metallization 170, which has a ring shape (detail not visible), which is formed, for example, by an aluminum and copper alloy and extends above the shield contact regions 70, in direct contact.

The transistor 10 also comprises four peripheral contacts 69, which are visible only in FIG. 2 and are arranged symmetrically with respect to the first and the second symmetry planes SP1, SP2. In particular, although not shown, the four peripheral contacts 69 extend through the front dielectric region 36, in such a way that a first pair of peripheral contacts 69 penetrates inside one of the two second perimeter trenches 21, while a second pair of peripheral contacts 69 penetrates inside the other second perimeter trench 21. Each peripheral contact 69 contacts the corresponding shield region 46 and the corresponding elongated gate region 52. Furthermore, although not shown, the peripheral contacts 69 may be formed by corresponding multilayer conductive structures, each of which comprises for example a region of titanium nitride (TiN) and an overlying region of tungsten (W). Furthermore, the peripheral contacts 69 may contact the shield metallization 170, so as to be short-circuited with each other.

The transistor 10 further comprises a passivation region 101, which is formed for example by a nitride and an oxide and extends above the body-source metallization 140 and the shield metallization 170.

In practice, the transistor 10 is a vertically conducting device, wherein the conductive channels are formed in the portions of body subregions 29 that extend below the source subregions 37, in contact with portions of external dielectric layers 32. Furthermore, it will be noted how, owing to the fact that only the ends of the shield regions penetrate inside the first perimeter trenches 19, and therefore owing to the absence, inside the first perimeter trenches 19, of shield regions having an elongated shape parallel to the X axis, the transistor 10 is characterized by a high voltage BVDss. Furthermore, the transistor 10 may be manufactured without the need to resort to complex technologies for controlling the distance between the trenches. Furthermore, in this embodiment, the shield contact regions 70 function as gate and shield contact.

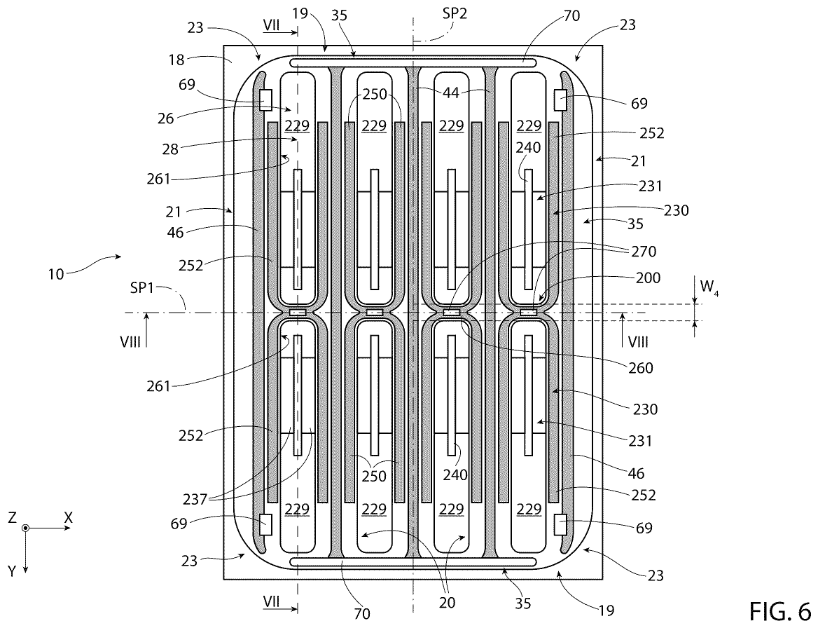

FIG. 6 shows a possible variant, which is now described with reference to the differences with respect to what has been shown in FIGS. 2-5; elements already present in FIGS. 2-5 are indicated with the same reference signs, unless otherwise specified.

In detail, an intermediate trench 200 extends into the semiconductor body 12 in an approximately symmetrical manner with respect to the first symmetry plane SP1. In top view, the intermediate trench 200 has an elongated shape parallel to the X axis and has a width W₄ (measured along the Y axis), which is approximately invariant for translations along the X axis and is, for example, approximately equal to the width W₁.

In greater detail, the intermediate trench 200 extends inside the semiconductor body 12 starting from the front surface Sₜₒₚ, with a depth approximately equal, for example, to the depth of the first and the second perimeter trenches 19, 21 and the internal trenches 20. Furthermore, the ends of the intermediate trench 200 communicate respectively with the second perimeter trenches 21.

The intermediate trench 200 divides each body subregion 29 into a corresponding pair of elementary body regions 229, which are arranged symmetrically with respect to the first symmetry plane SP1. In the example shown, for simplicity only eight elementary body regions 229 are present.

Furthermore, the transistor 10 comprises two source regions 230, which are arranged on opposite sides of the intermediate trench 200. Each source region 230 is divided into respective source region subparts 231 by the internal trenches 20. Furthermore, the transistor 10 comprises, for each source region 230, a number of corresponding body-source contact regions 240 equal to the number of respective source region subparts 231 (in the present example, four). As regards the shape and arrangement of these corresponding body-source contact regions 240 with respect to the source region 230, what has been described with reference to the body-source contact regions 40 and the source region 30 applies, therefore each body-source contact region 240 divides the corresponding source region subparts 231 into a pair of source subregions 237, which are separated from each other and extend on opposite sides of the body-source contact region 240, wherewith they are in direct contact. Although not shown, the body-source contact regions 240 of each source region 230 are put into electrical contact by a corresponding body-source metallization, for example in the same manner already described with reference to the body-source contact regions 40 and to the body-source metallization 140. Inside each internal trench 20, in the place of each elongated gate region 50, a corresponding pair of elongated gate regions 250 are present, which are again formed by polysilicon and extend on opposite sides of the intermediate trench 200, symmetrically with respect to the first symmetry plane SP1, and have elongated shapes parallel to the Y axis, aligned with each other. Although not shown, the elongated gate regions 250 extend inside the respective internal trenches 20 approximately starting from the front surface Sₜₒₚ and have again a thickness approximately equal to or greater than the thickness of the body region 28.

Inside each second perimeter trench 21, in the place of the respective elongated gate region 52 a corresponding pair of elongated gate regions 252 are present, which are again formed by polysilicon, extend symmetrically with respect to the first symmetry plane SP1 and have elongated shapes parallel to the Y axis, aligned with each other.

Both the elongated gate regions 250 and the elongated gate regions 252 each have a respective end which penetrates the intermediate trench 200 and an opposite end which is arranged facing a corresponding first perimeter trench 19, wherefrom it is arranged at a distance. Consequently, both the elongated gate regions 250 and the elongated gate regions 252 are arranged at a distance from the first perimeter trenches 19.

In greater detail, the elementary body regions 229 are arranged so as to form two successions of elementary body regions 229, these two successions being arranged on opposite sides of the intermediate trench 200. Furthermore, also the elongated gate regions 250 and the elongated gate regions 252 form two successions along the X axis of elongated gate regions, these two successions being arranged on opposite sides of the intermediate trench 200. Each elementary body region 229 is interposed between two corresponding adjacent elongated gate regions of the respective succession. Furthermore, each source region subpart 231 is interposed between two corresponding adjacent elongated gate regions of the respective succession.

The transistor 10 further comprises, for each pair of elementary body regions 229 arranged symmetrically with respect to the intermediate trench 200, a corresponding transversal gate region 260, which extends into the portion of intermediate trench 200 which is interposed between the two elementary body regions 229 and contacts with the four ends close to the intermediate trench 200 of the corresponding elongated gate regions, so as to form a pair of patterned gate regions 261, which in top view are approximately ‘U’-shaped and are arranged symmetrically with respect to the first symmetry plane SP1, with the two ends of each ‘U’-shape arranged facing a corresponding first perimeter trench 19, the two ‘U’-shapes being in contact with each other, in such a way that the two patterned gate regions 261 are joined with each other and form a single polysilicon region having a double-′U′-shape.

In practice, the transistor 10 comprises, in the place of the annular gate regions 61, the patterned gate regions 261, which are separated from the first perimeter trenches 19. Consequently, the shield contact regions 70 do not contact the patterned gate regions 261. Furthermore, the peripheral contacts 69 also do not contact the patterned gate regions 261, but only the shield regions 46. Although not shown, the shield metallization 170 is still in contact with the peripheral contacts 69.

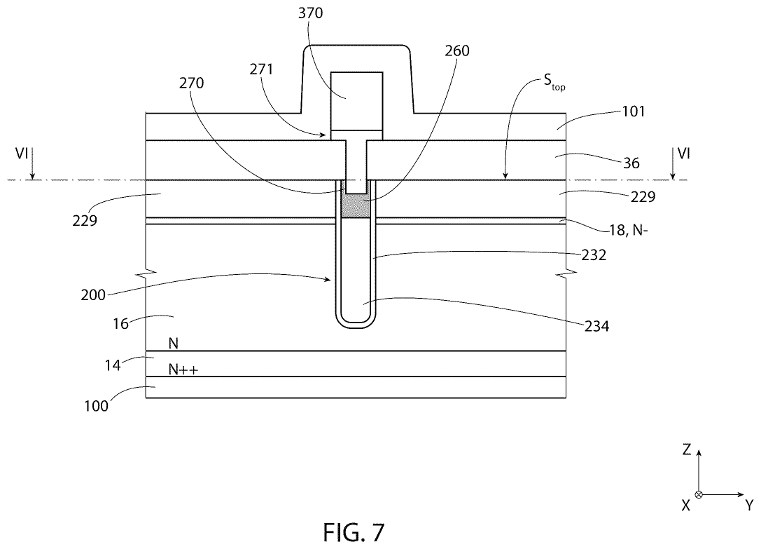

As shown in FIG. 7, inside the intermediate trench 200 a corresponding internal dielectric region 234 is present, which is formed, for example, by TEOS oxide and is surrounded laterally and at the bottom, in direct contact, by a corresponding external dielectric layer 232, which coats the side walls and the bottom of the intermediate trench 200. For ease of view, the distinction between external dielectric layer 232 and internal dielectric region 234 is not shown in FIG. 6. Although not shown, the external dielectric layer 232 contacts the external dielectric layers 32 present in the internal trenches 20 and in the second perimeter trenches 21; the internal dielectric region 234 contacts the internal dielectric regions 34 present in the internal trenches 20 and in the second perimeter trenches 21.

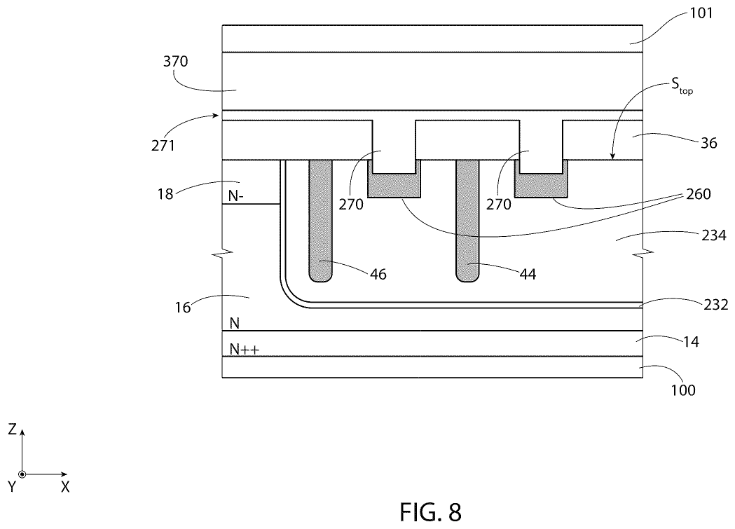

Furthermore, as shown in FIGS. 7 and 8, each transversal gate region 260 extends inside the intermediate trench 200 approximately starting from the front surface Sₜₒₚ and with approximately the same thickness as the elongated gate regions 250 and the elongated gate regions 252. Furthermore, each transversal gate region 260 is laterally separated from the two corresponding elementary body regions 229 by corresponding portions of the external dielectric layer 232 and contacts at the bottom with the internal dielectric region 234.

As shown in FIGS. 6-8, the transistor 10 further comprises, for each transversal gate region 260, a corresponding gate contact region 270, which traverses the front dielectric region 36 so as to contact, at the bottom, the corresponding transversal gate region 260. Furthermore, as visible in FIG. 8, the gate contact regions 270 extend partly above the front dielectric region 36 so as to form a single conductive gate contact structure 271, which puts in electrical contact the transversal gate regions 260 and is overlaid, in direct contact, by a gate metallization 370, which is formed, for example, by an aluminum and copper alloy and is in turn overlaid by the passivation region 101.

In practice, the shield metallization 170 forms an electrical contact of the sole shield regions 44, 46, this contact being electrically decoupled from the patterned gate regions 261. Furthermore, the gate metallization 370 electrically contacts the patterned gate regions 261, but it is electrically decoupled from the shield regions 44, 46. Consequently, in this variant the transistor 10 has gate and shield contacts independent of each other. The patterned gate regions 261 and the shield regions 44, 46 may therefore be biased independently of each other, while maintaining the same advantages in terms of increase in the voltage BVDss already described previously.

The transistor 10 may be manufactured, for example, by the manufacturing method described hereinbelow with reference, by way of example, to the embodiment shown in FIGS. 2-5. Furthermore, for the sake of brevity, details of the manufacturing process related to parts of the transistor 10 arranged below the substrate 14 are not described or shown hereinbelow.

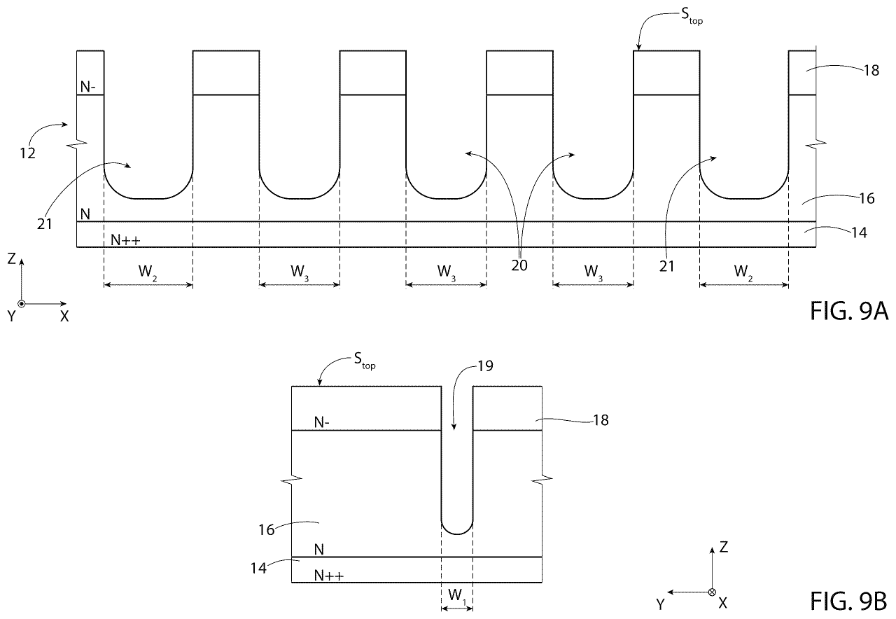

Initially, as shown in FIG. 9A and FIG. 9B, the substrate 14, the first and the second epitaxial layers 16, 18 are formed in a per se known manner. Furthermore, the first and the second perimeter trenches 19, 21 and the internal trenches 20 are formed.

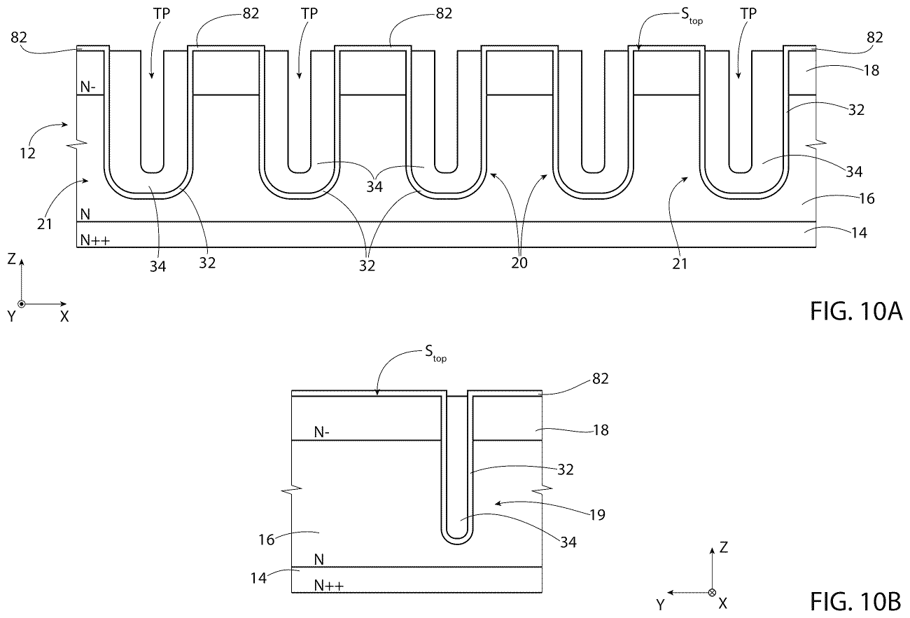

Then, as shown in FIGS. 10A and 10B, a thermal oxidation process and a subsequent TEOS oxide deposition process are performed, so as to form the internal dielectric regions 34, which form a single TEOS oxide region, and the external dielectric layers 32, which form a single thermal oxide region together with a first process layer 82 of thermal oxide, which extends above the portions of the second epitaxial layer 18 arranged outside the edge trench 25 and above the portions of the second epitaxial layer 18 interposed between the internal trenches 20 and the first and the second perimeter trenches 19, 21.

Furthermore, the TEOS oxide deposition process is such that, as visible in FIG. 10B, the internal dielectric region 34 present in each first perimeter trench 19 fills, together with the corresponding external dielectric layer 32, the first perimeter trench 19. Instead, both in the second perimeter trenches 21 and in the internal trenches 20, the internal dielectric regions 34 do not completely fill the trenches, but rather delimit, laterally and at the bottom, corresponding preliminary cavities TP, as visible in FIG. 10A. Although not shown, the ends of the preliminary cavities TP present in the internal trenches 20 partially each penetrate inside the corresponding first perimeter trench 19. In other words, the TEOS oxide deposition process progresses on the vertical walls of each trench in a such a way that the internal dielectric regions 34 that are formed in each first perimeter trench 19 completely close the portions of first perimeter trench 19 interposed between the internal trenches 20.

During this step of the manufacturing process, the internal dielectric regions 34 present in the first and the second perimeter trenches 19, 21 and in the internal trenches 20 also occupy the portions of the corresponding trenches intended to be occupied by the annular gate regions 61.

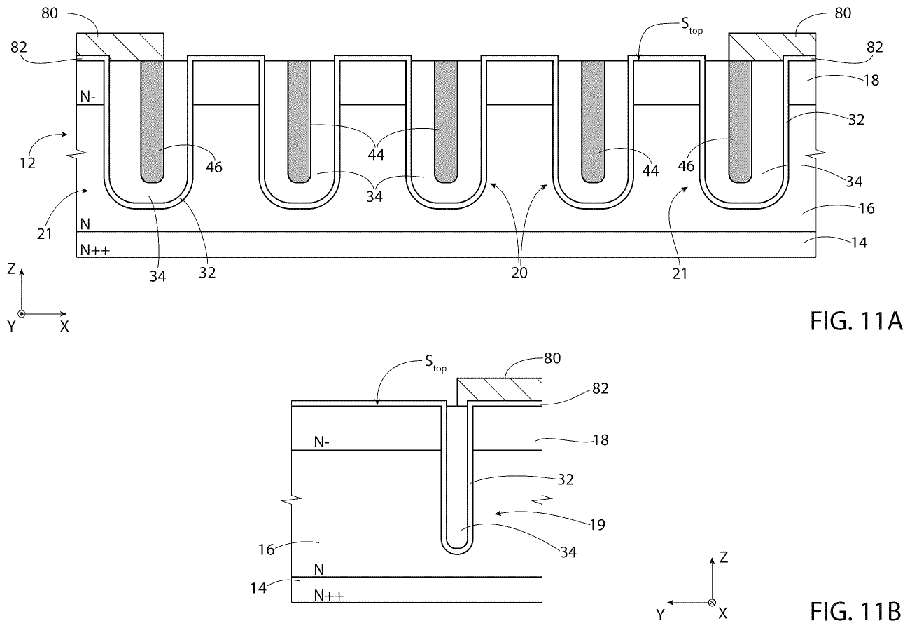

Subsequently, as shown in FIGS. 11A and 11B, the shield regions 44 and the shield regions 46 are formed, respectively inside the preliminary cavities TP in the internal trenches 20 and inside the preliminary cavities TP of the second perimeter trenches 21. For this purpose, for example, there are performed a deposition of polysilicon inside the preliminary cavities TP and a subsequent removal of the part (not shown) of deposited polysilicon which extends outside the internal trenches 20 and the second perimeter trenches 21. Owing to that only the ends of the preliminary cavities TP formed in the internal trenches 20 extend inside the first perimeter trenches 19, only the ends of the shield regions 44 penetrate inside the first perimeter trenches 19, as previously explained.

In addition, both the shield regions 44 present in the internal trenches 20 and the shield regions 46 present in the second perimeter regions 21 are surrounded laterally and at the bottom by the corresponding internal dielectric regions 34.

Subsequently, as shown again in FIGS. 11A and 11B, a resist mask 80 is arranged above the front surface Sₜₒₚ, which overlies: the shield regions 46 and the portions of the corresponding internal dielectric regions 34 are arranged outside the shield regions 46 (i.e., on the side of the shield regions 46 opposite with respect to the internal region 26 of the semiconductor body 12), as well as the portions of the external dielectric layers 32 interposed between the aforementioned portions of the corresponding internal dielectric regions 34 and the semiconductor body 12. Furthermore, portions of the internal dielectric regions 34 are arranged in the first perimeter trenches 19 arranged facing the opposite direction with respect to the internal region 26 of the semiconductor body 12, as well as portions of the corresponding external dielectric layers 32 adjacent to the latter, as shown in FIG. 11b. In practice, in each first perimeter trench 19, the mask 80 leaves exposed a portion of the corresponding internal dielectric region 34, this portion being arranged facing the internal region 26 of the semiconductor body 12.

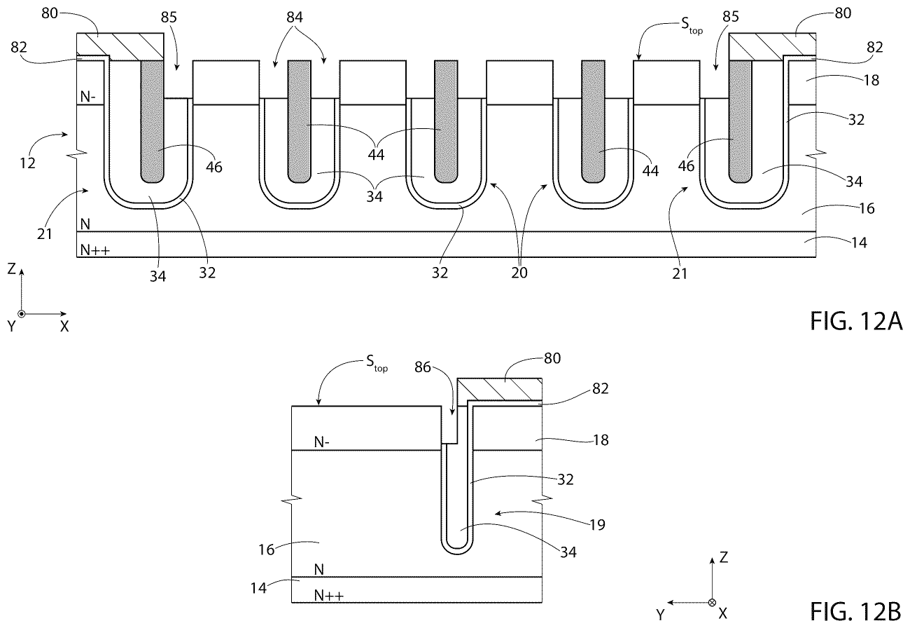

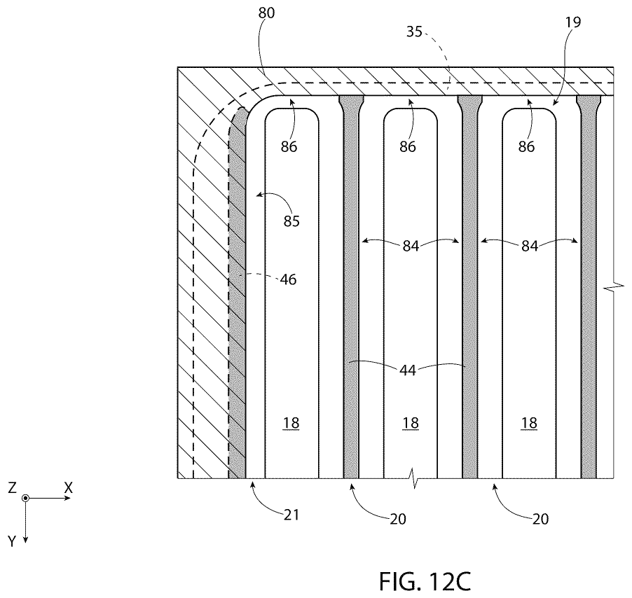

Then, as shown in FIGS. 12A, 12B, and 12C, an etching (e.g., a time, wet-type or plasma etching) is performed through the mask 80, so as to selectively remove dielectric material, without etching the semiconductor material. In particular, the etching allows to selectively remove the portions of first process layer 82 left exposed by the mask 80. The etching further selectively removes, for each internal trench 20, a pair of portions of the corresponding internal dielectric region 34 that are arranged on opposite sides of the upper portion of the corresponding shield region 44 and portions of the corresponding external dielectric layer 32 that are arranged respectively in contact with this pair of portions of the corresponding internal dielectric region 34, so as to expose the upper portion of the corresponding shield region 44 and portions of the second epitaxial layer 18 that face the internal trench 20, as well as to form a pair of corresponding temporary cavities 84 that extend on opposite sides of the shield region 44 and are precisely laterally delimited by the upper portion of the shield region 44 and by corresponding exposed portions of second epitaxial layer 18. Still further, the etching selectively removes, for each second perimeter trench 21, a portion of the corresponding internal dielectric region 34 that is interposed between the upper portion of the corresponding shield region 46 and the internal region 26 of the semiconductor body 12, as well as a portion of the corresponding external dielectric layer 32 that is interposed between the aforementioned portion of the corresponding internal dielectric region 34 and the internal region 26 of the semiconductor body 12, so as to expose one side of the upper portion of the corresponding shield region 46 and a portion of the second epitaxial layer 18 that faces the second perimeter trench 21, as well as to form a corresponding temporary cavity 85. Also, the etching selectively removes, for each first perimeter trench 19, parts of the portion of the corresponding internal dielectric region 34 left exposed by the mask 80 and portions of the corresponding external dielectric layer 32 interposed between said parts of the portion of the corresponding internal dielectric region 34 left exposed by the mask 80 and the internal region 26 of the semiconductor body 12, so as to expose portions of the second epitaxial layer 18 that face the first perimeter trenches 19, as well as to form, in each first perimeter trench 19, corresponding temporary cavities 86.

In practice, the exposure of the aforementioned portions of the second epitaxial layer 18 is obtained, inter alia, by removing corresponding portions of external dielectric layers 32. In this regard, the etching is such that the removal of dielectric material occurs, for example, in an anisotropic manner. Furthermore, as visible in FIGS. 12B and 12C, each temporary cavity 86 has an approximately elongated shape parallel to the Y axis and is delimited at the bottom and on one own first side by the internal dielectric region 34 of the respective first perimeter trench 19 and is delimited, on one own second side opposite to the first side, by a portion of the second epitaxial layer 18 which faces the first perimeter trench 19.

In greater detail, as visible in FIG. 12C, each temporary cavity 86 communicates with a pair of adjacent temporary cavities 84 or with a temporary cavity 85 and with the temporary cavity 84 adjacent to the latter. Furthermore, in each first perimeter trench 19, adjacent temporary cavities 86 are separated by corresponding ends of the shield regions 44.

Then, the mask 80 is removed. Furthermore, in a manner per se optional and not shown here, a process of formation and subsequent removal of a sacrificial oxide (not shown) may be performed on the exposed portions of the shield regions 44, 46, in order to improve the interface between silicon and gate oxide. Hereinafter, for simplicity it is assumed that this process of formation and subsequent removal of a sacrificial oxide is not performed.

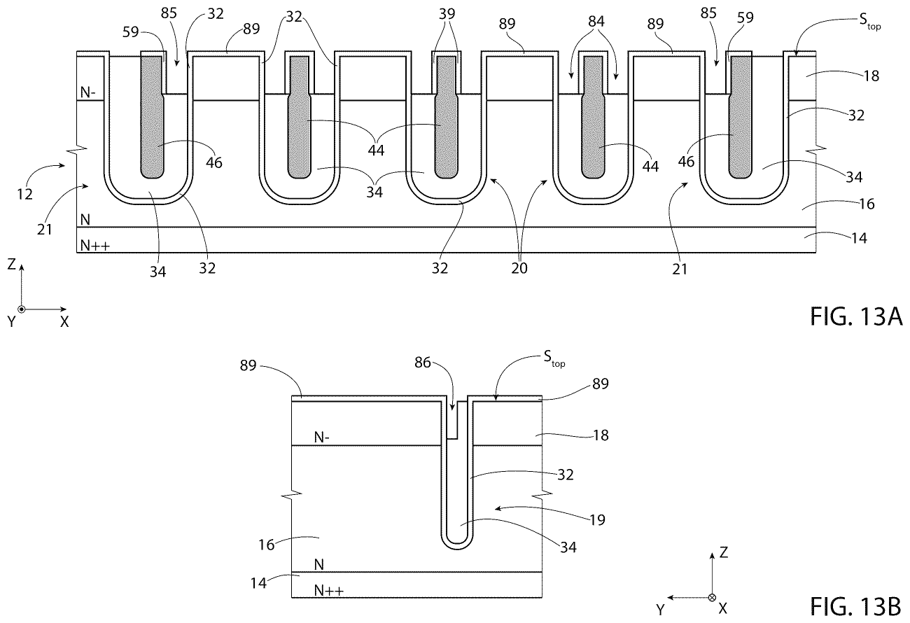

Subsequently, as shown in FIGS. 13A and 13B, a thermal oxidation process is performed, in such a way as to restore the portions of the external dielectric layers 32 previously removed and form the dielectric coating layers 39, 59. This oxidation also entails the formation of a second process layer 89 of thermal oxide, which extends above the second epitaxial layer 18 and the shield regions 44, 46 and is intended to form part of the front dielectric region 36. Furthermore, this oxidation entails a reduction in the width (measured along the X axis) of the upper portions of the shield regions 44, 46, with respect to the width of the corresponding lower portions.

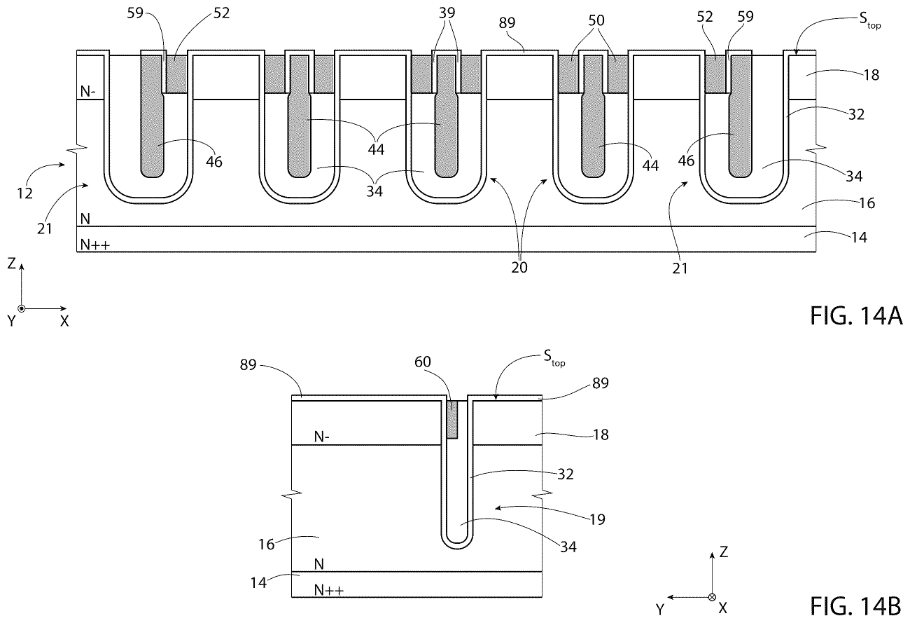

Subsequently, as shown in FIGS. 14A and 14B, the elongated gate regions 52, the elongated gate regions 50 and the transversal gate regions 60 are formed, respectively, in the temporary cavities 85, in the temporary cavities 84 and in the temporary cavities 86. In this manner, the annular gate regions 60 are formed. For example, the elongated gate regions 52, the elongated gate regions 50 and the transversal gate regions 60 are formed by a deposition of polysilicon, for example with an N-type doping, and a subsequent “etch-back” process to remove the polysilicon portions (not shown) arranged above the front surface Sₜₒₚ, and in particular above the second process layer 89.

Then, the manufacturing process proceeds in a manner known per se and therefore not shown, with the formation of the front dielectric region 36 (for example, by front deposition of a layer of silicon nitride) and the execution of implants of P-type doping species for the formation of the body region 28 and the enriched body contact regions 42. Then, an implant of N-type doping species is performed, to form the source region 30. Subsequently, the body-source contact regions 40, the shield contact regions 70 and the peripheral contacts 69 are formed, in a per se know manner.

The embodiment shown in FIGS. 6-8 may be manufactured by using the same manufacturing process previously described, with the following modifications.

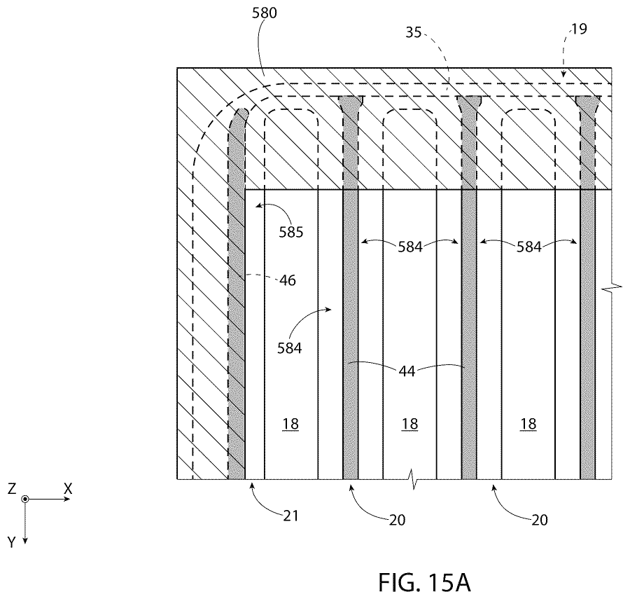

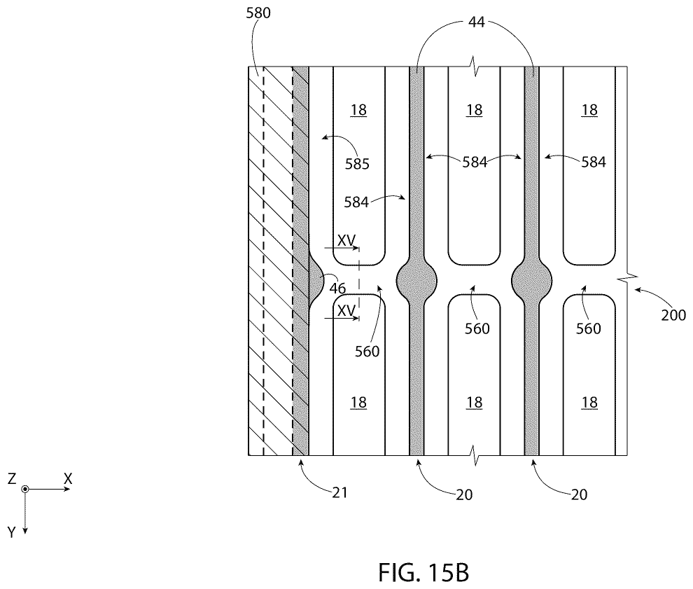

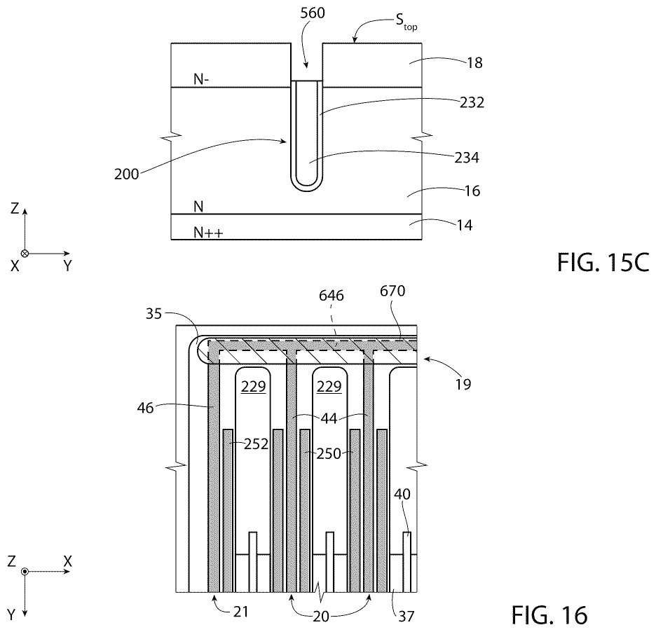

In particular, as shown in FIG. 15A, the resist mask (here indicated by 580) entirely overlies the first perimeter trenches 19 as well as portions of the internal trenches 20 adjacent to the first perimeter trenches 19, so as to protect the dielectric material contained therein. In this manner, the execution of the etching previously mentioned with reference to FIGS. 12A-12C does not cause the formation, in the first perimeter trenches 19, of the temporary cavities 86. Furthermore, the temporary cavities (here indicated by 584 and 585) which are formed respectively in the internal trenches 20 and in the second perimeter trenches 21 extend at a distance from the first perimeter trenches 19 and are intended to accommodate the elongated gate regions 250 and the elongated gate regions 252, respectively. Furthermore, as visible in FIGS. 15B and 15C, the execution of the etching previously mentioned with reference to FIGS. 12A-12C causes the formation, inside the intermediate trench 200, of one succession of temporary cavities 560, which are intended to house the transversal gate regions 260 and, as visible in FIG. 15C, are delimited at the bottom by corresponding portions of the external dielectric layer 232 and the internal dielectric region 234 and are laterally delimited by corresponding exposed portions of the second epitaxial layer 18. Adjacent temporary cavities 560 are separated by corresponding portions of the shield regions 44.

Then, the manufacturing process proceeds in the same manner as previously described.

The advantages that the present transistor affords are clear from the preceding description, in particular as regards the increase in the voltage BVDss with respect to transistors of known types, without the need to make use of complex manufacturing technologies. The increase in the voltage BVDss is obtained owing to that, in each first perimeter trench 19, the ends of the adjacent shield regions 44 are in any case laterally separated from each other due to the interposition of portions of the corresponding dielectric trench region 35 and, in the case of the embodiment shown in FIGS. 2-5, also of the corresponding transversal gate regions 60.

Finally, it is clear that modifications and variations may be made to the transistor and the manufacturing process previously described, without departing from the scope of the present invention, as defined in the attached claims.

For example, number, shape and arrangement of peripheral contacts 69 may vary from what has been described; the same presence of the peripheral contacts 69 is optional. The enriched body contact regions 42 may be absent.

The shape of the shield regions, the elongated gate regions and the transversal gate regions may vary from what has been described. For example, in the case of the embodiment shown in FIGS. 6-8, the shield regions 44 may include enlarged regions at the internal trench 200, as shown in FIG. 15B. More generally, the shapes of the shield regions and the elongated gate regions may not be approximately invariant for translations along the respective elongation directions.

The types of doping may be reversed with respect to what has been described.

The second epitaxial layer 18 may be absent.

Finally, as shown in FIG. 16, unclaimed variants are possible, which differ from what has been shown in FIGS. 6-8 for the presence, in each first perimeter trench 19 (only one shown in FIG. 16), of a corresponding transversal shield region 646 of polysilicon, which has an elongated shape parallel to the X axis and contacts the shield regions 44 and the shield 5 regions 46.

Although not shown in FIG. 16, the gate contact regions 270 still allow to contact the patterned gate regions 261, while the shield contact regions, indicated here by 670 (only one visible in FIG. 16, shown with a diagonal dashed line) contact the underlying transversal shield regions 646. In this manner, the shield and gate contacts are independent of each other.

1. A MOSFET transistor, comprising:
a semiconductor body;
a plurality of internal trenches extending into the semiconductor body and having elongated shapes parallel to a first direction and arranged in succession;
a pair of edge trenches extending into the semiconductor body and having elongated shapes parallel to a second direction transversal to the first direction;
wherein ends of each internal trench communicate with a corresponding edge trench of the pair of edge trenches;
for each edge trench of the pair of edge trenches, a corresponding dielectric trench region extends into the edge trench;
for each internal trench of the plurality of internal trenches:
a conductive shield region extending inside the internal trench and having an elongated shape parallel to the first direction; and
a first pair of conductive gate regions extending into the internal trench on opposite sides of the conductive shield region and having elongated shapes parallel to the first direction; and
wherein ends of each conductive shield region penetrate inside a corresponding edge trench; and
wherein, in each edge trench, the ends of adjacent conductive shield regions are separated from each other.

2. The MOSFET transistor according to claim 1, wherein, in each edge trench, the ends of adjacent conductive shield regions are separated by portions of the corresponding dielectric trench region.

3. The MOSFET transistor according to claim 1, wherein each edge trench has a first width, measured in a direction perpendicular to the second direction; and wherein each internal trench has a second width, measured in a direction perpendicular to the first direction; and wherein the first width is smaller than the second width.

4. The MOSFET transistor according to claim 1, further comprising a plurality of annular gate regions, wherein each annular gate region is formed of a same material as the conductive gate regions and comprises a corresponding pair of conductive gate regions and a pair of transversal gate regions, wherein each transversal gate region extends into a corresponding edge trench and contacts the corresponding conductive gate region.

5. The MOSFET transistor according to claim 4, further comprising, for each edge trench, a corresponding gate-shield contact region formed by conductive material and which overlies, in direct contact, the corresponding transversal gate regions and the corresponding ends of the conductive shield regions.

6. The MOSFET transistor according to claim 4, wherein the semiconductor body comprises an epitaxial region having a first conductivity type and delimited by a front surface, and a plurality of body regions having a second conductivity type and extending inside the epitaxial region starting from the front surface; and wherein pairs of adjacent internal trenches laterally delimit, together with corresponding portions of the edge trenches, corresponding body regions; and wherein pairs of conductive gate regions that extend into adjacent internal trenches and are arranged facing a same body region are separated from said body region by corresponding dielectric gate regions; said MOSFET transistor further comprising, for each body region, a corresponding source region of the first conductivity type extending into a portion of the body region starting from the front surface.

7. The MOSFET transistor according to claim 1, further comprising:
an intermediate trench extending into the semiconductor body and having an elongated shape parallel to the second direction, wherein said intermediate trench is interposed at a distance between the edge trenches and communicates with the internal trenches such that the edge trenches, the internal trenches and the intermediate trench laterally delimit two successions of semiconductive subregions of the semiconductor body, each semiconductive subregion of one succession being arranged symmetrically with respect to a corresponding semiconductive subregion of the other succession, with respect to the intermediate trench;
for each internal trench, a second pair of conductive gate regions extending on opposite sides of the corresponding conductive shield region, symmetrically with respect to the corresponding first pair of conductive gate regions, the end of each conductive gate region arranged facing the opposite direction with respect to the intermediate trench being arranged at a distance with respect to the corresponding edge trench;
for each pair of symmetric semiconductive subregions, a corresponding transversal gate region formed of the same material as the conductive gate regions and extending into a portion of the intermediate trench interposed between the two symmetric semiconductive subregions; and
wherein pairs of conductive gate regions that extend into adjacent internal trenches and are arranged facing a same semiconductive subregion are separated from said same semiconductive subregion by corresponding dielectric gate regions and contact the corresponding transversal gate region, wherewith they form a patterned gate region having a ‘U’-shape.

8. The MOSFET transistor according to claim 7, further comprising:
for each edge trench, a corresponding shield contact region formed by conductive material and overlying, in direct contact, the corresponding ends of the conductive shield regions; and
for each transversal gate region, a corresponding gate contact region formed by conductive material and overlying, in direct contact, the corresponding transversal gate region, the gate contact regions being in electrical contact with each other.

9. The MOSFET transistor according to claim 8, wherein the semiconductor body comprises:
an epitaxial region having a first conductivity type and delimited by a front surface; and
a plurality of body regions having a second conductivity type and each extending into a corresponding semiconductive region;
said MOSFET transistor further comprising, for each body region, a corresponding source region of the first conductivity type extending into a portion of the body region starting from the front surface.

10. The MOSFET transistor according to claim 1, further comprising an annular trench comprising the edge trenches and extending into the semiconductor body to delimit an internal region of the semiconductor body, said internal trenches extending into the internal region of the semiconductor body.

11. A process for manufacturing a MOSFET transistor, comprising:
forming a plurality of internal trenches extending into a semiconductor body and having elongated shapes parallel to a first direction and arranged in succession; and
forming a pair of edge trenches extending into the semiconductor body and having elongated shapes parallel to a second direction transversal to the first direction;
wherein ends of each internal trench communicate with a corresponding edge trench;
forming, in each edge trench, a corresponding dielectric trench region;
for each internal trench:
forming a conductive shield region extending inside the internal trench and having an elongated shape parallel to the first direction; and
forming a first pair of conductive gate regions extending into the internal trench on opposite sides of the conductive shield region and having elongated shapes parallel to the first direction; and
wherein ends of each conductive shield region penetrate inside a corresponding edge trench; and
wherein, in each edge trench, the ends of adjacent conductive shield regions are separated from each other.

12. The manufacturing process according to claim 11, wherein, in each edge trench, the ends of adjacent conductive shield regions are separated by portions of the corresponding dielectric trench region.

13. The manufacturing process according to claim 11, further comprising forming a plurality of annular gate regions made of a same material as the conductive gate regions, each annular gate region comprising a corresponding pair of conductive gate regions and a pair of transversal gate regions, each transversal gate region extending into a corresponding edge trench and contacting the corresponding conductive gate regions.

14. The manufacturing process according to claim 13, further comprising forming, for each edge trench, a corresponding gate-shield contact region formed by conductive material and overlying, in direct contact, the corresponding transversal gate regions and the corresponding ends of the conductive shield regions.

15. The manufacturing process according to claim 11, further comprising:
forming an intermediate trench extending into the semiconductor body and having an elongated shape parallel to the second direction, wherein the intermediate trench is interposed at a distance between the edge trenches and communicates with the internal trenches such that the edge trenches, the internal trenches and the intermediate trench laterally delimit two successions of semiconductive subregions of the semiconductor body, wherein each semiconductive subregion of one succession is arranged symmetrically with respect to a corresponding semiconductive subregion of the other succession, with respect to the intermediate trench;
for each internal trench, forming a second pair of conductive gate regions extending on opposite sides of the corresponding conductive shield region, symmetrically with respect to the corresponding first pair of conductive gate regions, the end of each conductive gate region arranged facing the opposite direction with respect to the intermediate trench being arranged at a distance with respect to the corresponding edge trench;
for each pair of symmetric semiconductive subregions, forming a corresponding transversal gate region made of the same material as the conductive gate regions and extending into a portion of the intermediate trench interposed between the two symmetric semiconductive subregions; and
wherein pairs of conductive gate regions that extend into adjacent internal trenches and are arranged facing a same semiconductive subregion are separated from said same semiconductive subregion by corresponding dielectric gate regions and contact the corresponding transversal gate region, wherewith they form a patterned gate region having a ‘U’-shape.

16. The manufacturing process according to claim 15, further comprising:
for each edge trench, forming a corresponding shield contact region formed by conductive material and overlying, in direct contact, the corresponding ends of the conductive shield regions; and
for each transversal gate region, forming a corresponding gate contact region formed by conductive material and overlying, in direct contact, the corresponding transversal gate region, the gate contact regions being in electrical contact with each other.

17. The manufacturing process according to claim 11, wherein the edge trenches have a first width measured in a direction perpendicular to the second direction; and wherein the internal trenches have a second width measured in a direction perpendicular to the first direction, and wherein the first width is smaller than the second width;
said manufacturing process further comprising:
after having formed the edge trenches and the internal trenches, forming dielectric material in the edge trenches and in the internal trenches to form, in the edge trenches, the corresponding dielectric trench regions which close the portions of the corresponding edge trenches interposed between the internal trenches, and where the dielectric material formed in the internal trenches laterally delimits corresponding preliminary cavities; and
forming the conductive shield regions in the preliminary cavities.

18. The manufacturing process according to claim 17, further comprising:
following the formation of the conductive shield regions, selectively removing dielectric material from the internal trenches to form temporary cavities laterally delimited by front portions of the shield regions and by exposed portions of the semiconductor body;
coating the front portions of the shield regions and the exposed portions of the semiconductor body which laterally delimit the temporary cavities with corresponding dielectric layers; and
then forming the conductive gate regions in the temporary cavities.
